(19) United States
(12) Patent Application Publication
(10) Pub. No.: US 2007/0099356 A1
(43) Pub. Date: May 3, 2007

(54) Flat panel display device and method of manufacturing the same

(75) Inventors: Jin-Seong Park, Suwon-si (KR); Taek Ahn, Suwon-si (KR); Min-Chul Suh, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung SDI Co., Ltd., Suwon-si (KR)

(21) Appl. No.: 11/588,362

(22) Filed: Oct. 27, 2006

(30) Foreign Application Priority Data
Nov. 3, 2005 (KR) 2005-104923

(51) Int. Cl. H01L 21/84; H01L 21/00; G02F 1/1335

(52) U.S. Cl. 438/149; 349/5

(57) ABSTRACT

A flat panel display device of which a display unit is efficiently sealed and which has good flexibility, and a method of manufacturing the flat panel display. The flat panel display device includes a substrate, a display unit formed on the substrate, and a sealing part formed so as to cover the display unit using an atomic layer deposition (ALD) method.

### CROSS-REFERENCE TO RELATED PATENT APPLICATIONS

This application claims the benefit of Korean Patent Application No. 2005-104923, filed Nov. 3, 2005, in the Korean Intellectual Property Office, the disclosure of which is incorporated herein in its entirety by reference.

### BACKGROUND OF THE INVENTION

1. Field of the Invention

Aspects of the present invention relate to a flat panel display device and a method of manufacturing the flat panel display device, and more particularly, to a flat panel display device of which a display unit is efficiently sealed and which has good flexibility, and a method of manufacturing the flat panel display device.

2. Description of the Related Art

Generally, flat panel display devices include a display unit formed on a flat substrate, and a member protecting the display unit from the outside. In particular, when a display element included in the display unit can be easily damaged by external impurities such as moisture, oxygen, or the like, the member protecting the display unit from the outside prevents the impurities from entering the display unit.

A conventional member protecting the display unit is formed of glass or metal. In order to prevent display units from deteriorating due to impurities such as moisture, oxygen, or the like that enter through the conventional member protecting the display unit, a moisture absorbent, or the like may be applied to the protecting member. However, since the conventional member protecting the display unit has a poor flexibility, the conventional member protecting the display unit cannot be used in flexible display devices that are recently being extensively researched and in high demand. In addition, since the moisture absorbent or the like that is applied to the protecting member is not transparent, when light generated in the display unit passes through the protecting member, the brightness of the light can decrease. Furthermore, the non-transparent moisture absorbent cannot efficiently prevent impurities that easily deteriorate display elements.

### SUMMARY OF THE INVENTION

Aspects of the present invention provide a flat panel display device of which a display unit is efficiently sealed and which has good flexibility, and a method of manufacturing the flat panel display device.

According to an aspect of the present invention, there is provided a flat panel display device comprising: a substrate; a display unit formed on the substrate; and a sealing part formed so as to cover the display unit using an atomic layer deposition (ALD) method.

While not required in all aspects, the sealing part may be an inorganic insulating layer. The sealing part may be formed of aluminum oxide. The sealing part may be formed of silicon oxide. The sealing part may be formed on an entire surface of the substrate so as to cover the display unit. The display unit may comprise an organic light emitting element.

According to another aspect of the present invention, there is provided a method of manufacturing a flat panel display device, comprising: forming a display unit on a substrate; and forming a sealing part so as to cover the display unit using an ALD method.

While not required in all aspects, the sealing part may be an inorganic insulating layer. The sealing part may be formed of aluminum oxide. The sealing part may be formed of silicon oxide. The forming of the sealing part may comprise forming the sealing part on an entire surface of the surface so as to cover the display unit using the ALD method.

The display unit may comprise an organic light emitting element.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 illustrates a schematic cross sectional view of a flat panel display device according to an embodiment of the present invention;

FIG. 2 illustrates a schematic cross sectional view of a subpixel of the flat panel display device of FIG. 1, according to an embodiment of the present invention; and

FIG. 3 is a schematic cross sectional view illustrating a subpixel of a flat panel display device according to another embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

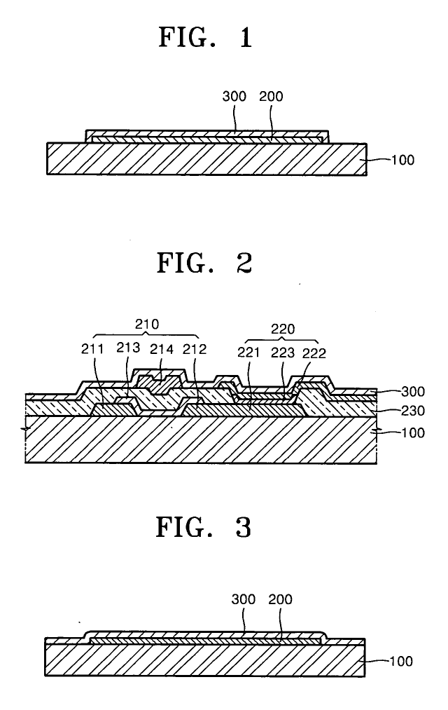

FIG. 1 illustrates a schematic cross sectional view of a flat panel display device according to an embodiment of the present invention.

Referring to FIG. 1, a display unit 200 is formed on a substrate 100. A part 300 covers the display unit 200 and is formed using an atomic layer deposition (ALD) method. In the present embodiment, the substrate 100 may be a glass substrate, a plastic substrate such as a substrate formed of acryl having good flexibility and a metal substrate, but the present invention is not limited thereto.

The display unit 200 may include various display elements such as a liquid crystal display (LCD) element or an organic light emission element. An organic light emission element as illustrated in FIG. 2 has good flexibility. Hereinafter, the case where the display unit 200 of FIG. 1 includes the organic light emission element will be described with reference to FIG. 2.

A display unit of an organic light emitting display device includes the organic light emitting element. In the present embodiment, the organic light emitting display device may be of various types of organic light emitting displays. Referring to FIG. 2, the organic light emitting display device is an active matrix organic light emitting display including a thin film transistor (TFT) 210 formed on each subpixel.

Each of the subpixels includes at least one TFT 210. Referring to FIG. 2, a buffer layer (not shown) formed of SiO₂, or the like may be accordingly formed on the substrate 100. A source electrode 211 and a drain electrode 212 are formed on the resulting structure. A semiconductor layer 213 contacting with each of the source electrode 211 and the drain electrode 212 is formed on the resulting structure. An insulating layer 230 covering the resulting structure and the TFT 210 including a gate electrode 214 are formed.

The insulating layer 230 also functions as a pixel definition layer that defines a pixel of an organic light emitting element 220. The flat panel display device according to the present invention is not limited to a structure including the TFT 210 as illustrated in FIG. 2. That is, the flat panel display device may include TFTs of various types. Alternatively, the flat panel display device may include an organic TFT of which one element is formed of an organic material.

Although not illustrated in FIG. 2, the TFT 210 may contact with at least one capacitor. A circuit including the TFT 210 is not limited to the structure as illustrated in FIG. 2, and the circuit may vary accordingly.

The TFT 210 is electrically connected to the organic light emitting element 220, which is a display element. The organic light emitting element 220 includes a pixel electrode 221, an opposite electrode 222 and an intermediate layer 223 including an emissive layer interposed between the pixel electrode 221 and the opposite electrode 222. In the organic light emitting display device, according to an embodiment of the present invention, the pixel electrode 221 of the organic light emitting element 220 and the drain electrode 212 of the TFT 210 are integrally formed. The flat panel display device according to the present invention is not limited to the structure of FIG.2, and the flat panel display device may have various structures accordingly.

The opposite electrode 222 of the organic light emitting element 220 may be formed as a single body in a plurality of pixels. The intermediate layer 223 of the organic light emitting element 220 is patterned to correspond only to a subpixel as illustrated in FIG. 2, which illustrates the structure of the subpixel for clarity. The intermediate layer 223 may be formed as a single body in adjacent subpixels. Some parts of the intermediate layer 223 are formed respectively in each subpixel, and other parts of the intermediate layer 223 are integrally formed in adjacent subpixels. That is, a structure of the intermediate layer 223 may vary accordingly.

The pixel electrode 221 of the organic light emitting element 220 is an anode electrode, the opposite electrode 222 is a cathode electrode, or vice versa.

The pixel electrode 221 may be a transparent electrode or a reflective electrode. As the transparent electrode, the pixel electrode 221 may be indium tin oxide (ITO), indium zinc oxide (IZO), zinc oxide (ZnO) or indium oxide (In₂O₃). As the reflective electrode, the pixel electrode 221 may be formed using a method in which a reflective layer is formed using Ag, Mg, Al, Pt, Pd, Au, Ni, Nd, Ir, Cr, compounds thereof, or the like and ITO, IZO, ZnO or In₂O₃ is formed thereon.

The opposite electrode 222 may be also a transparent electrode or a reflective electrode. As the transparent electrode, the opposite electrode 222 is formed using a method in which Li, Ca, LiF/Ca, LiF/Al, Al, Mg or compounds thereof are deposited towards the intermediate layer 223 and an auxiliary electrode or a bus electrode line is formed on the resulting structure, using materials for forming the transparent electrode such as ITO, IZO, ZnO, In₂O₃, or the like. As the reflective electrode, the opposite electrode 222 is formed by totally depositing Li, Ca, LiF/Ca, LiF/Al, Al, Mg, or compounds thereof towards the intermediate layer 223 and to form the auxiliary electrode or the bus electrode line thereon.

The intermediate layer 223 that is formed between the pixel electrode 221 and the opposite electrode 222 may be a small-molecular weight organic layer or a polymer organic layer. When the intermediate layer 223 is a small-molecular weight organic layer, the intermediate layer 223 may have a structure including one or combinations of a hole injection layer (HIL), a hole transport layer (HTL), an emission layer (EML), an electron transport layer (ETL), an electron injection layer (EIL), or the like. Examples of organic materials for the small-molecular weight organic layer include copper phthalocyanine (CuPc), N,N-di(naphthalene-1-yl)-N,N′-diphenyl-benzidine (NPB), tris-8-hydroxyquinoline aluminum (Alq₃), etc. The small-molecular weight organic layer can be formed using a vacuum deposition method that employs a mask.

When the intermediate layer 223 is a polymer organic layer, the intermediate layer 223 has a structure including an HTL and an EML. The HTL may be formed of poly-3,4-ethylenedioxythiophene (PEDOT), and the EML may be formed of a poly-para-phenylenevinylene(PPV)-based or polyfluorene-based polymer material using a screen printing method, an inkjet printing method, etc.

A sealing part 300 covers the organic light emitting element 220 and the thin film transistor 210. The sealing part 300 protects the organic light emitting element 220 and the TFT 210 from outer mechanical impacts, and the sealing part 300 prevents impurities such as moisture, oxygen, or the like from entering from the outside. The sealing part 300 is formed using an atomic layer deposition (ALD) method, and the sealing part 300 may be an organic insulating layer formed of silicon oxide or aluminum oxide.

That is, the display unit 200 is formed on the substrate 100. The resulting structure is inserted into a chamber. Then, a first reaction resource is fed into the chamber (first feeding operation). A first material layer is formed using a deposition method. Then, after a first purge operation in which the first reaction resource is removed, a second reaction resource is fed into the chamber (second feeding operation). A first material layer, which is already formed, reacts with the second reaction resource. Then, the first material layer becomes the sealing part 300 having desired ingredients. In addition, a second purge operation may be processed. That is, the remaining second reaction resource, which did not react with the first material layer, or a generated residual product is removed.

For example, when the sealing part 300 is an aluminum oxide (Al₂O₃) layer, the sealing part 300 is formed by a method including depositing a trimethylaluminum (TMA:Al(CH₃)₃) layer, feeding water vapor, ozone, or the like, and heat-treating the TMA:Al(CH₃)₃ layer so as to induce a surface reaction with the water vapor or ozone in order to transform the TMA:Al(CH₃)₃ layer into the Al₂O₃ layer.

The sealing part 300 having desired compositions may be uniformly formed on a large area using the ALD method. By repeating the operations, the thickness of the sealing part 300 can be regulated, and the sealing part 300 can be formed to have a plurality of layers.

Since the sealing part 300 formed using the above method is a thin film formed using a surface reaction, the thickness of the sealing part 300 is uniform and the sealing part 300 is uniformly formed even in a complicated structure such as steps, or the like. The sealing part 300 prevents oxygen or moisture from the outside from penetrating the flat panel display device. Since the sealing part 300 is a thin film, the sealing part 300 has good flexibility. Since the thickness of the sealing part 300 is uniform, a flat panel display device can display a good image even when the flat panel display device is a top emission type of flat panel display device in which light passes to the outside. Since the sealing part 300 is a thin film, the brightness of light emitted from the display unit 200 does not decrease.

In the current embodiment of the present invention, the organic light emitting display device, of which display unit 200 includes an organic light emitting element, is described with reference to FIG. 2. However, the flat panel display device according to the current embodiment of the present invention can be various kinds of flat panel display devices.

FIG. 3 is a schematic cross sectional view illustrating a subpixel of a flat panel display device according to another embodiment of the present invention.

The flat panel display device according to the current embodiment of the present invention is different from the flat panel display device of FIG. 2 in that a sealing part 300 is formed on an entire surface of a substrate 100 so as to cover a display unit 200. That is, since the sealing part 300 completely covers the display unit 200 from the outside, the sealing part 300 can maximize a sealing effect for the display unit 200.

The flat panel display device according to aspects of the present invention and a method of manufacturing the same can obtain the following advantages.

First, a sealing part having desired compositions can be uniformly formed on a large area using an ALD method.

Second, the sealing part can be formed to have a uniform thickness, and the sealing part can be uniformly formed even on structures having steps.

Third, the flat panel display device can efficiently prevent oxygen, moisture, or the like from entering, and the flat panel display device can have good flexibility.

Fourth, since the sealing part is formed to have a uniform thickness, the flat panel display device can display a good image even when the flat panel display device is a top emission type flat panel display device in which light passes to the outside. Since the sealing part is a thin film, the brightness of light emitted from a display unit does not decrease.

Fifth, since the sealing part can be formed using a low-temperature process, the sealing part can be used even with a substrate such as a plastic substrate, or the like having poor thermostability. In addition, during the process of forming the sealing part, members such as organic light emission elements are prevented from being damaged because of heat.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A flat panel display device comprising:
a substrate;
a display unit formed on the substrate; and
a sealing part formed so as to cover the display unit using an atomic layer deposition (ALD) method.

2. The flat panel display device of claim 1, wherein the sealing part is an inorganic insulating layer.

3. The flat panel display device of claim 1, wherein the sealing part is formed of aluminum oxide.

4. The flat panel display device of claim 1, wherein the sealing part is formed of silicon oxide.

5. The flat panel display device of claim 1, wherein the sealing part is formed on an entire surface of the substrate so as to cover the display unit.

6. The flat panel display device of claim 1, wherein the display unit comprises an organic light emitting element.

7. The flat panel display device of claim 1, wherein the display unit comprises a top emission type of flat panel display device.

8. A method of manufacturing a flat panel display device, comprising:
forming a display unit on a substrate; and
forming a sealing part so as to cover the display unit using an atomic layer deposition (ALD) method.

9. The method of claim 8, wherein the sealing part is an inorganic insulating layer.

10. The method of claim 8, wherein the sealing part is formed of aluminum oxide.

11. The method of claim 8, wherein the forming of the sealing part comprises:
depositing a first material layer so as to cover the display unit; and
depositing a second material, wherein a surface reaction between the first material and the second material forms the sealing part.

12. The method of claim 8, wherein the forming of the sealing part so as to cover the display unit is performed at about room temperature.

13. The method of claim 8, wherein the forming the sealing part comprises:
depositing a trimethylaluminum (TMA:Al(CH₃)₃), layer so as to cover the display unit;
feeding water vapor or ozone; and
transforming the TMA layer to an aluminum oxide layer by heat-treating the TMA layer so as to induce a surface reaction with the water vapor or ozone.

14. The method of claim 8, wherein the sealing part is formed of silicon oxide.

15. The method of claim 8, wherein the forming of the sealing part comprises forming the sealing part on an entire surface of the substrate so as to cover the display unit using the ALD method.

16. The method of claim 8, wherein the display unit comprises an organic light emitting element.
